(19) United States
(12) Patent Application Publication
(10) Pub. No.: US 2025/0369112 A1
(43) Pub. Date: Dec. 4, 2025

(54) ATOMIC LAYER DEPOSITION APPARATUS

(71) Applicant: SAMSUNG ELECTRONICS CO., LTD., Suwon-si (KR)

(72) Inventors: Jinyoung LEE, Suwon-si (KR); Sunghyup KIM, Suwon-si (KR); Yebin NAM, Suwon-si (KR); Sukwon LEE, Suwon-si (KR)

(73) Assignee: SAMSUNG ELECTRONICS CO., LTD., Suwon-si (KR)

(21) Appl. No.: 19/020,593

(22) Filed: Jan. 14, 2025

(30) Foreign Application Priority Data
May 30, 2024 (KR) 10-2024-0070573

(51) Int. Cl. C23C 16/455; C23C 16/458; C23C 16/52

(52) U.S. Cl. CPC C23C 16/45544; C23C 16/458; C23C 16/52

(57) ABSTRACT

An atomic layer deposition apparatus includes: a substrate mounting plate configured to have a substrate mounted thereon; a housing including an internal space in which the substrate mounting plate is accommodated; a reactant supplier including a plurality of regions respectively corresponding to a plurality of zones of the substrate; and a product measurer configured to measure a thickness of a product deposited on each of the plurality of zones, wherein the housing further includes a plurality of supply holes respectively corresponding to the plurality of regions and configured to allow a reactant to pass into the internal space from the reactant supplier, and the reactant supplier is configured to supply the reactant to the plurality of zones through the plurality of regions and the plurality of supply holes.

### CROSS-REFERENCE TO RELATED APPLICATION(S)

This application is based on and claims priority to Korean Patent Application No. 10-2024-0070573 filed on May 30, 2024 in the Korean Intellectual Property Office, the disclosure of which is incorporated herein by reference in its entirety.

### BACKGROUND

The present disclosure relates to an atomic layer deposition apparatus.

The atomic layer deposition process is generally superior to a chemical vapor deposition (CVD) process in terms of thickness distribution of a deposited film. However, if a precursor and an agent, the main reactants of the atomic layer deposition process, are improperly supplied to a substrate surface on which deposition is to be performed, the deposition of the precursor or the generation of the film may not be uniform. Depending on the substrate position, the generation of a non-uniform film may result in an uneven thickness distribution of the deposited film.

The reactants are generally distributed relatively evenly through a plurality of holes of a showerhead in a chamber and sprayed toward the substrate surface. However, while the reactants are sprayed evenly through the showerhead over time, the amount of the reactants that may actually reach the substrate surface and be used for the deposition may differ depending on the substrate positions due to differences in the conditions surrounding the substrate. As a result, the unevenness of the thickness distribution of the film deposited by the atomic layer deposition process may increase as the process progresses.

### SUMMARY

Provided is an atomic layer deposition apparatus that may reduce an unevenness thickness distribution of a film deposited by an atomic layer deposition process and reducing process costs.

According to an aspect of the disclosure, an atomic layer deposition apparatus includes: a substrate mounting plate configured to have a substrate mounted thereon; a housing including an internal space in which the substrate mounting plate is accommodated; a reactant supplier including a plurality of regions respectively corresponding to a plurality of zones of the substrate; and a product measurer configured to measure a thickness of a product deposited on each of the plurality of zones, wherein the housing further includes a plurality of supply holes respectively corresponding to the plurality of regions and configured to allow a reactant to pass into the internal space from the reactant supplier, and the reactant supplier is configured to supply the reactant to the plurality of zones through the plurality of regions and the plurality of supply holes.

According to an aspect of the disclosure, an atomic layer deposition apparatus includes: a substrate mounting plate configured to have a substrate mounted thereon; a housing including an internal space in which the substrate mounting plate is accommodated; a reactant supplier including a plurality of regions which respectively correspond to a plurality of zones of the substrate; and a product measurer configured to measure a thickness of a product deposited on each of the plurality of zones, wherein the housing further includes a plurality of supply holes respectively corresponding to the plurality of regions and configured to allow a reactant to pass into the internal space from the reactant supplier, the reactant supplier further includes a reactant source, a plurality of reactant supply lines connected to the reactant source and respectively connected to the plurality of regions, and a cover member covering the plurality of supply holes, the cover member is divided into the plurality of regions, and the plurality of reactant supply lines are respectively connected to the plurality of regions of the cover member.

According to an aspect of the disclosure, an atomic layer deposition apparatus includes: a substrate mounting plate configured to have a substrate mounted thereon; a housing including an internal space in which the substrate mounting plate is accommodated; a reactant supplier configured to supply a reactant to be deposited on the substrate; and a product measurer configured to measure a thickness of a product deposited on the substrate, wherein the housing further includes a plurality of supply holes configured to allow the reactant to pass into the internal space, and the product measurer includes a plurality of optical sensors configured to respectively measure the thickness of the product deposited on each of a plurality of zones of the substrate.

### BRIEF DESCRIPTION OF THE DRAWINGS

The above and other aspects and features of certain embodiments of the present disclosure will be more apparent from the following description taken in conjunction with the accompanying drawings, in which:

FIG. 1 is a schematic diagram illustrating an atomic layer deposition apparatus according to an example embodiment;

FIG. 2 is a schematic diagram illustrating an operation of an atomic layer deposition apparatus according to the related art;

FIG. 3 is a schematic diagram illustrating an operation of an atomic layer deposition apparatus according to an example embodiment;

FIGS. 4, 5, 6, and 7 are schematic diagrams illustrating the results of performing a process using an atomic layer deposition apparatus according to an example embodiment;

FIGS. 8, 9, 10, and 11 are schematic diagrams illustrating the results of performing a process using an atomic layer deposition apparatus according to the related art;

FIGS. 12, 13, 14, and 15 are schematic diagrams illustrating a point in time at which a minimum value of a coverage is 0.95 or greater (i.e., a point in time at which the distribution is less than 5%) during a process by an atomic layer deposition apparatus according to an example embodiment and an atomic layer deposition apparatus according to the related art;

FIG. 16 is a graph illustrating an average coverage of an atomic layer deposition apparatus according to an example embodiment and an atomic layer deposition apparatus according to the related art;

FIG. 17 is a graph illustrating a minimum coverage of an atomic layer deposition apparatus according to an example embodiment and an atomic layer deposition apparatus according to the related art;

FIG. 18 is a flowchart illustrating an atomic layer deposition method according

to an example embodiment; and

FIG. 19 is a configuration diagram illustrating an atomic layer deposition apparatus according to an example embodiment.

### DETAILED DESCRIPTION

Hereinafter, example embodiments of the present disclosure are described with reference to the accompanying drawings.

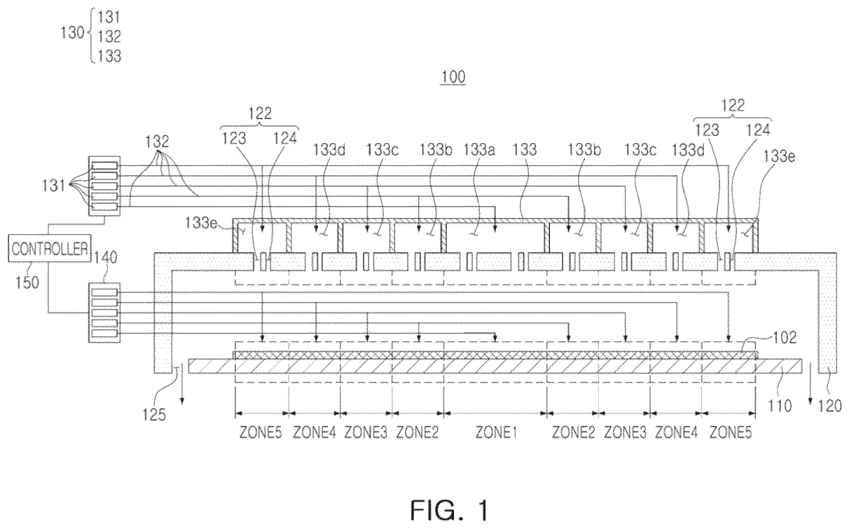

FIG. 1 is a configuration diagram illustrating an atomic layer deposition apparatus according to an example embodiment.

Referring to FIG. 1, an atomic layer deposition apparatus 100 according to an example embodiment includes a substrate mounting plate 110, a housing 120, a reactant supplier 130, a product measurer 140, and a controller 150.

The substrate mounting plate 110 has a plate shape, and a substrate 102 may be mounted on an upper surface thereof. As an example, the substrate mounting plate 110 may have a shape corresponding to a shape of the substrate 102 and may have a size larger than the substrate 102 so that the substrate 102 may be mounted on the upper surface thereof. For example, the substrate 102 may be fixed to the substrate mounting plate 110 during a process by electrostatic force and vacuum suction force. The substrate 102 mounted on the substrate mounting plate 110 may be roughly divided into five zones (zone 1 to zone 5) corresponding to a plurality of regions of the reactant supplier 130 described below.

The housing 120 may have an internal space in which the substrate mounting plate 110 is accommodated. As an example, the housing 120 may have a box shape with an open bottom. The housing 120 may include a plurality of supply holes 122 allowing reactants to be supplied to the internal space of the housing 120. The supply hole 122 may include a precursor spray hole 123 into which a precursor supplied through a reactant supplier 130 is sprayed and an agent spray hole 124 disposed to be adjacent to the precursor spray hole 123 and into which an agent is sprayed through the reactant supplier 130. The precursor spray hole 123 and the agent spray hole 124 form a pair of supply holes 122. As an example, the precursor spray hole 123 and the agent spray hole 124 may be selectively opened and closed. For example, when a precursor is supplied from the reactant supplier 130, the precursor spray hole 123 may be opened and the agent spray hole 124 may be closed, and when an agent is supplied from the reactant supplier 130, the precursor spray hole 123 may be closed and the agent spray hole 124 may be opened. To this end, the housing may include an opening/closing member. A lower portion of the housing 120 may be open, and an outlet 125 may be formed between the housing 120 and the substrate mounting plate 110. Accordingly, since the substrate mounting plate 110 is placed in the internal space of the housing 120, the precursor passing through the precursor spray hole 123 and flowing into the internal space of the housing 120 through a space formed between the substrate mounting plate 110 and the housing 120 and the agent passing through the agent spray hole 124 and flowing into the internal space of the housing 120 may be discharged to the outside of the housing 120 through the outlet 125.

The reactant supplier 130 supplies a reactant to be deposited on the substrate 102 mounted on the substrate mounting plate 110. To this end, the reactant supplier 130 may include a reactant source 131 in which the reactant is stored or received, a reactant supply line 132 connected to the reactant source 131, and a cover member 133 connected to the reactant supply line 132 and divided into a plurality of regions to cover the supply holes 122 of the housing 120. For example, the cover member 133 may be divided into five regions corresponding to the five zones of the substrate mounting plate 110 described above. In this manner, by the cover member 133 divided into five regions, a plurality of supply holes 122 provided in the housing 120 may be separated so as to be respectively arranged within the five regions of the cover member 133. For example, the cover member 133 may be divided into a first region 133a, a second region 133b, a third region 133c, a fourth region 133d, and a fifth region 133e, and the first region 133a, the second region 133b, the third region 133c, the fourth region 133d, and the fifth region 133e may be sequentially arranged from the center to the edge. In addition, the reactant supply lines 132 may be respectively connected to the first to fifth regions 133a to 133e. Accordingly, the supply amount of the reactant supplied to the first to fifth regions 133a to 133e may be separately controlled. Accordingly, the supply amount of the reactant supplied to the substrate 102 divided into the five zones (zone 1 to zone 5) mounted on the substrate mounting plate 110 may be separately controlled. The reactant supplier 130 may include a mass flow controller for controlling the supply amount of the reactant supplied to each of the first to fifth regions 133a to 133e. The mass flow controller may be installed in each reactant supply line 132 connected to the cover member 133 divided into five regions, or may be installed in the reactant source 131 divided into five regions and storing the reactant. However, the present disclosure is not limited thereto, and the installation position of the mass flow controller may be installed in the housing 120, etc., as long as the supply amount of the reactant supplied onto the substrate 102 divided into a plurality of regions may be controlled.

While the present example embodiment describes the cover member 133 divided into five regions, the present disclosure is not limited thereto, and the number of regions divided by the cover member 133 may vary. For example, the number of regions divided by the cover member 133 may be changed to 2, 3, 4, 6 or more, etc.

The product measurer 140 measures a thickness of a product deposited on the substrate 102. As an example, the product measurer 140 may measure the thickness of the product stacked on the upper surface of the substrate 102 divided into five zones (zone 1 to zone 5) corresponding to the first to fifth regions 133a to 133e described above. To this end, the product measurer 140 may include a plurality of sensors. As an example, the sensor may measure the thickness of the product stacked on the substrate 102 through an optical measurement method. However, without being limited thereto, any sensor capable of measuring the thickness of the product stacked on the substrate 102 may be employed. As an example, the product measurer 140 may include five sensors to respectively measure the thickness of the product stacked on the substrate 102 in the five zones.

The controller 150 may be connected to the reactant supplier 130 and the product measurer 140. As an example, the controller 150 may control the supply amount of the reactant supplied from the reactant supplier 130 through information on the thickness of the product deposited on the substrate 102 detected by the product measurer 140. For example, the controller 150 may receive information on the thickness of product stacked on the substrate 102 in each of a plurality of regions from the product measurer 140 and supply an appropriate amount of reactant according to the thickness of the product on the substrate 102 divided into a plurality of regions by controlling the reactant supplier 130.

Briefly, this will be described by taking as an example a case of spraying a precursor that directly affects a process thickness distribution and cost during a process of depositing a silicon nitride (SiNₓ) film using a gaseous diiodosilane (SiH₂I₂) precursor and a nitrogen radical (N radical) agent mixed in nitrogen (N₂) and a carrier gas on a silicon wafer.

When the precursor is supplied from the reactant supplier 130, the precursor spray hole 123 of the housing 120 is opened and the agent spray hole 124 is closed. Accordingly, the precursor may be supplied to the substrate 102 only through the precursor spray hole 123. Thereafter, a thickness of the precursor adsorbed to the surface of the substrate 102 by an adsorption reaction in each zone is detected by the product measurer 140, and the controller 150 derives the amount of the precursor adsorbed to the surface of the substrate 102 through information on the thickness of the precursor adsorbed to the surface of the substrate 102. Thereafter, the controller 150 calculates a coverage per position and time by dividing the amount of the precursor adsorbed to the surface of the substrate 102 by the amount of precursor that may be maximally deposited per unit area of the substrate surface. Here, a surface having a coverage of 0 calculated by the controller 150 is a surface on which the precursor is not deposited, and a surface having a coverage of 1 is a surface on which the precursor is completely deposited. Also, the controller 150 calculates a product shortage through the coverage. Here, the product shortage is calculated by surface-integrating (1-coverage) in each region. Thereafter, the controller 150 controls the amount of the precursor supplied from the reactant supplier 130 on the substrate divided into a plurality of regions based on the product shortage to be supplied.

As described above, the supply amount of the reactant supplied to each region from the reactant supplier 130 may be controlled through information on the thickness of the product deposited in each zone of the substrate 102 received from the product measurer 140. Accordingly, the thickness distribution of the deposited film may be reduced (i.e., disparities between zones may be reduced) and the usage amount of precursor may be reduced, thereby reducing the process costs.

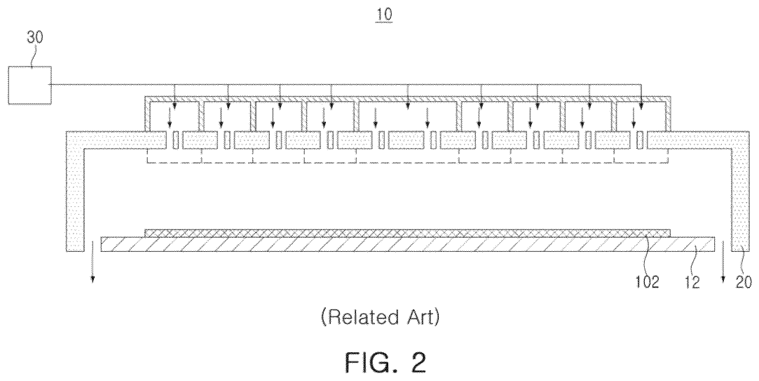

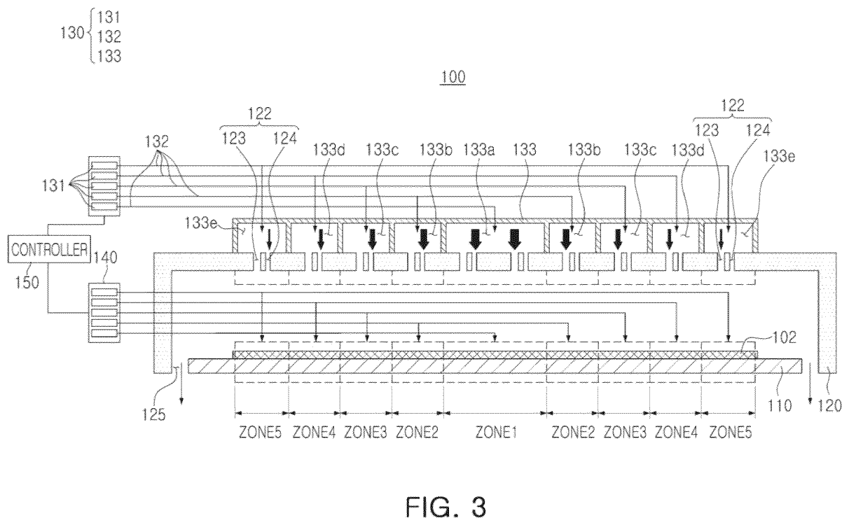

FIG. 2 is a diagram illustrating an operation of an atomic layer deposition apparatus according to the related art, and FIG. 3 is a diagram illustrating an operation of an atomic layer deposition apparatus according to an example embodiment.

As illustrated in FIG. 2, an atomic layer deposition apparatus 10 according to the related art provides a reactant supplied into the housing 20 uniformly throughout. Accordingly, the reactant is uniformly provided from the reactant supplier 30 onto the substrate 102 mounted on the substrate mounting base 12.

However, as illustrated in FIG. 3, the atomic layer deposition apparatus 100 according to an example embodiment controls and supplies the supply amount of the reactant onto the substrate 102 through the reactant supplier 130 having the reactant source 131 receiving the reactant, the reactant supply line 132 connected to the reactant source 131, and the cover member 133 connected to the reactant supply line 132, divided into a plurality of regions, and disposed to cover the supply hole 122 of the housing 120, so that an appropriate amount of the reactant may be supplied onto the substrate divided into the plurality of zones.

When the atomic layer deposition apparatus 10 and 100 illustrated in FIGS. 2 and 3 perform the atomic layer deposition process, the substrate in the atomic layer deposition process is a silicon wafer on which patterning of 300 nm size has not been performed. In addition, in the atomic layer deposition process, an operation of spraying a precursor, directly affecting a process thickness distribution and cost during the process of depositing a silicon nitride (SiNₓ) film, is performed using a gaseous diiodosilane (SiH₂I₂) precursor and a nitrogen radical (N radical) agent mixed in nitrogen (N₂) and a carrier gas, respectively, on a silicon wafer. In the atomic layer deposition apparatus 100 according to an example embodiment, the reactant supplier 130 and the product measurer 140 correspond in a one-to-one manner on a substrate 102 divided into five zones. Also, the controller 150 calculates the coverage per position and time by dividing the amount of the precursor adsorbed to the surface of the substrate 102 by an adsorption reaction in each zone by the product measurer 140 by the amount of the precursor that may be deposited maximally per unit area of the substrate surface. Here, a surface having a coverage of 0 calculated by the controller 150 is a surface on which the precursor is not deposited, and a surface having a coverage of 1 is a surface on which the precursor is completely deposited. Also, the controller 150 calculates a product shortage through the coverage. Here, the product shortage is calculated by surface-integrating (1-coverage) in each region.

The total amounts of the precursor supplied per hour through the supply holes of the atomic layer deposition apparatuses 10 and 100 illustrated in FIGS. 2 and 3 are the same, and the supply amounts of the precursor per hour per supply hole belonging to the same region are the same. Other external conditions (shape, temperature, pressure, etc.) are the same.

Hereinafter, performance results of the process performed under the above conditions are described.

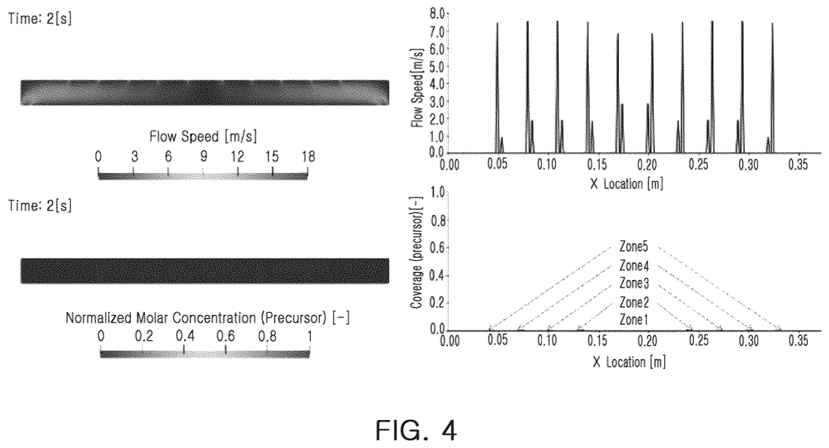

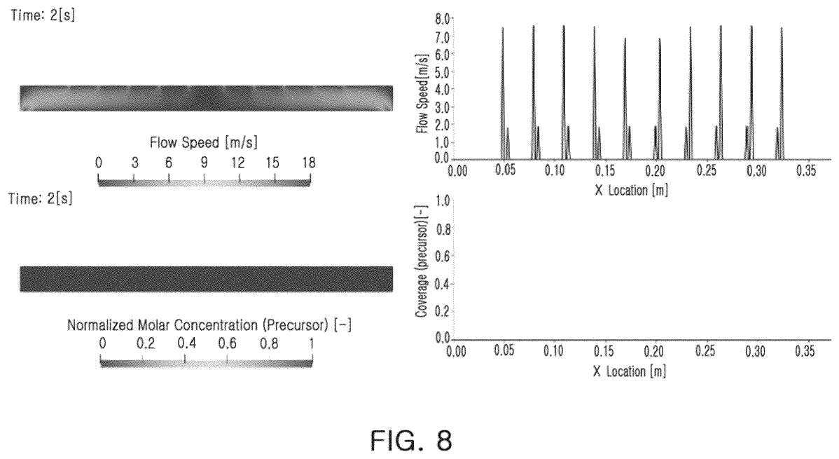

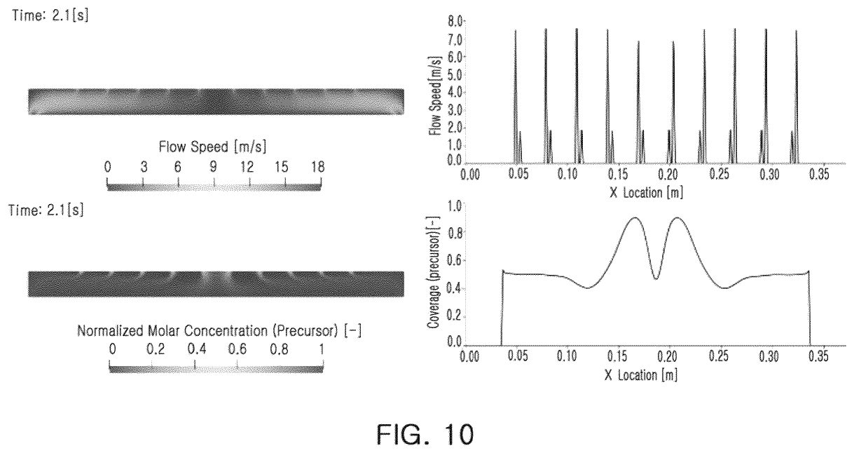

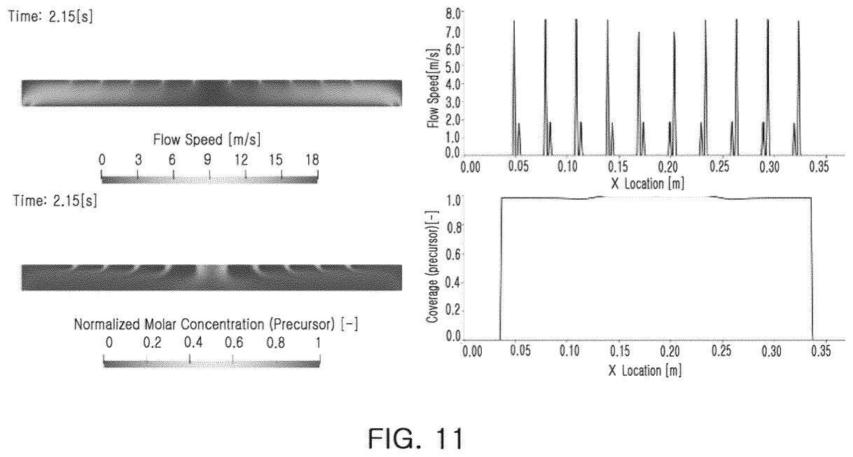

FIGS. 4 to 7 are diagrams illustrating process performance results by an atomic layer deposition apparatus according to an example embodiment, and FIGS. 8 to 11 are diagrams illustrating process performance results by an atomic layer deposition apparatus according to the related art.

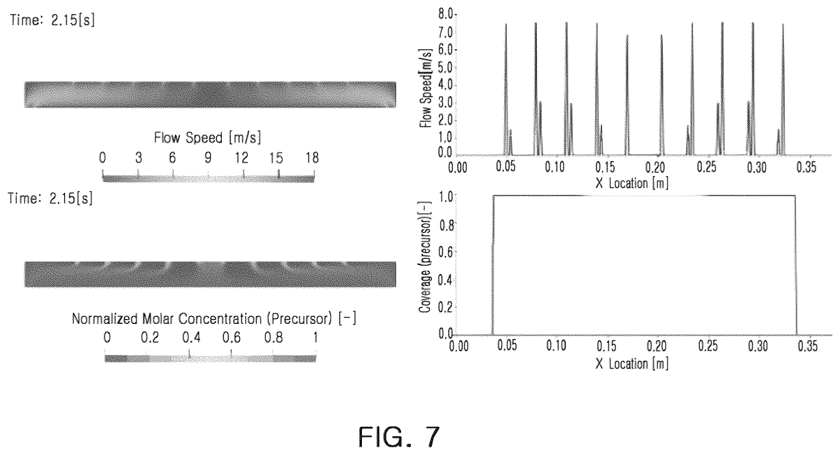

First, FIGS. 4 and 7 show the process performance results 2 s before the process, at which time only a transport gas was sprayed, without precursor spraying, to stabilize a field.

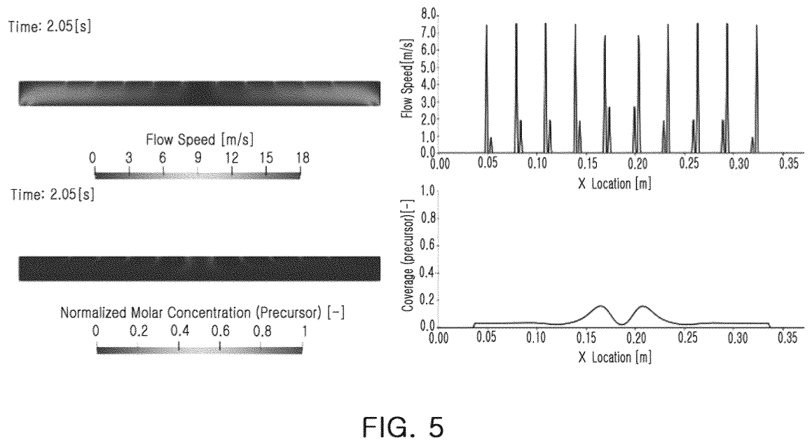

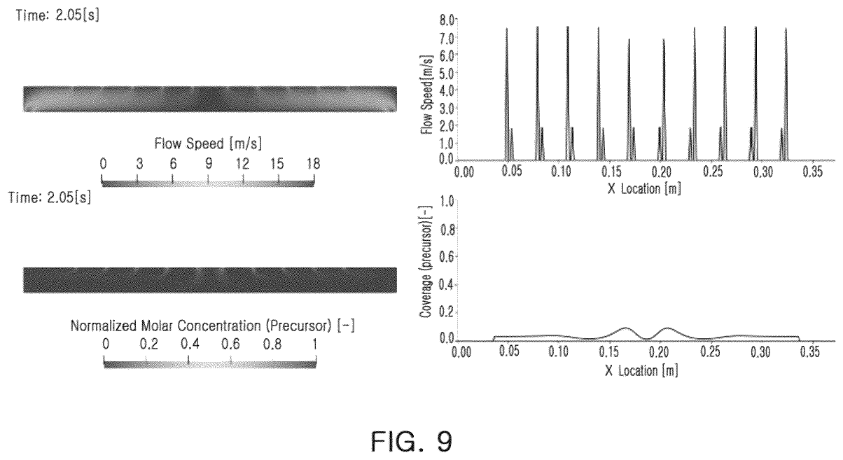

FIGS. 5 to 7 are diagrams illustrating the process performance results from 2 s to 2.15 s of the atomic layer deposition apparatus 100 (see FIG. 1) according to an example embodiment, and FIGS. 9 to 11 are diagrams illustrating the process performance results from 2 s to 2.15 s of the atomic layer deposition apparatus 10 (see FIG. 2) according to the related art.

The sub-drawings illustrated on the top left of FIGS. 4 to 11 are diagrams illustrating a flow speed, the sub-drawings illustrated on the bottom left of FIGS. 4 to 11 are diagrams illustrating normalized molar concentration, the sub-drawings illustrated on the top right of FIGS. 4 to 11 are diagrams illustrating a spray speed through a supply hole, and the sub-drawings illustrated on the bottom right of FIGS. 4 to 11 are diagrams illustrating a coverage of a precursor.

First, referring to FIGS. 4 to 7, it can be seen that, when the process is performed by the atomic layer deposition apparatus 100 illustrated in FIG. 1, the overall coverage increases over time due to the spraying and deposition reactions of the precursor. In addition, referring to FIGS. 8 to 11, it can be also seen that, when the process is performed by the atomic layer deposition apparatus 10 according to the related art illustrated in FIG. 2, the overall coverage increases over time due to the spraying of the precursor and deposition reactions.

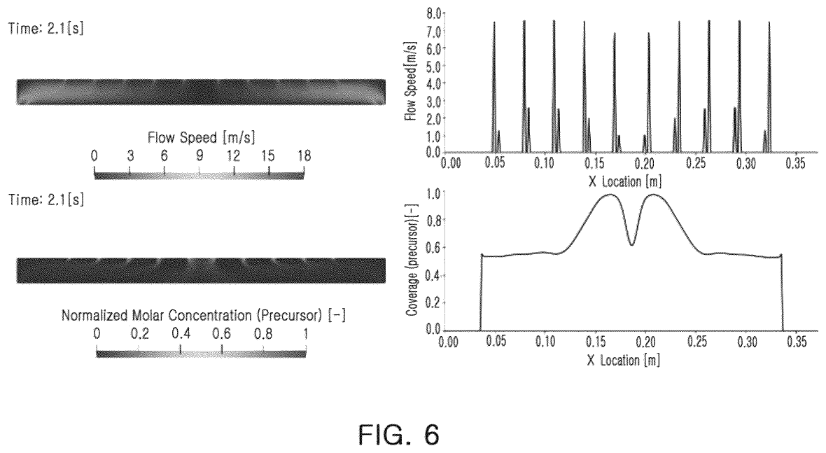

However, as illustrated in FIGS. 5 to 7, in the case of the atomic layer deposition apparatus 100 (see FIG. 1) according to an example embodiment, it can be seen that the supply amount of the reactant is adjusted for each region according to the relative product shortage in each region over time. That is, as illustrated in FIG. 4, the coverage is the highest at approximately 0.165 m and approximately 0.21 m, and the supply amount of the reactant is also the largest at approximately 0.165 m and approximately 0.21 m. Also, as illustrated in FIG. 5, the supply rate is the highest at approximately 0.165 m and approximately 0.21 m, but the supply amount of the reactant is also the smallest at approximately 0.165 m and approximately 0.21 m. Also, as illustrated in FIG. 6, the supply rate is constant overall, and the supply amount of the reactant is different in each region.

However, in the case of the atomic layer deposition apparatus according to the related art 10 (see FIG. 2), as illustrated in FIGS. 8 to 11, the supply amount of the reactant is constant in each region, and the coverage increases rapidly overall.

Hereinafter, performance results of the process are described with reference to the drawings in more detail.

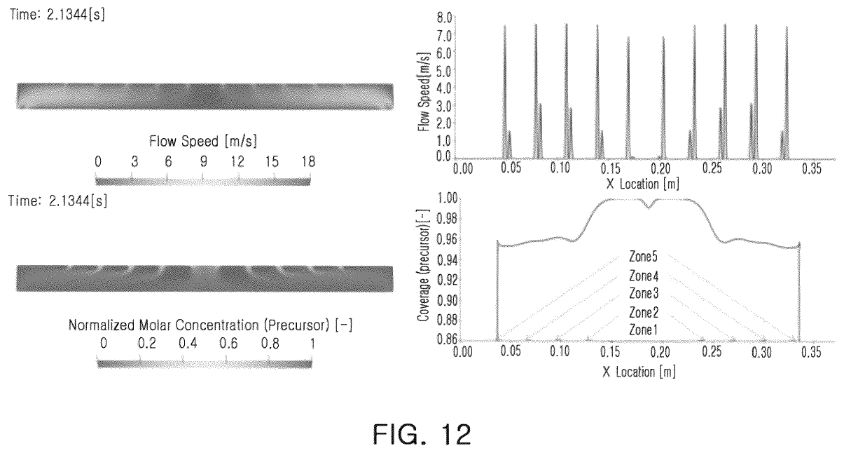

In order to compare and analyze the atomic layer deposition apparatus 100 (see FIG. 1) according to an example embodiment and the atomic layer deposition apparatus 10 (see FIG. 2) according to the related art from the viewpoint of an operating time, points in time when the minimum value of the coverage during the process becomes 0.95 or greater (i.e., a point in time at which the distribution becomes less than 5%) by the atomic layer deposition apparatus 100 (see FIG. 1) according to an example embodiment and the atomic layer deposition apparatus 10 (see FIG. 2) according to the related art were found and are illustrated in FIGS. 12 to 15.

Also, for a detailed comparison, the range of the Y-axis in FIGS. 12 to 15 is reduced to 0.86 to 1, compared to FIGS. 4 to 11.

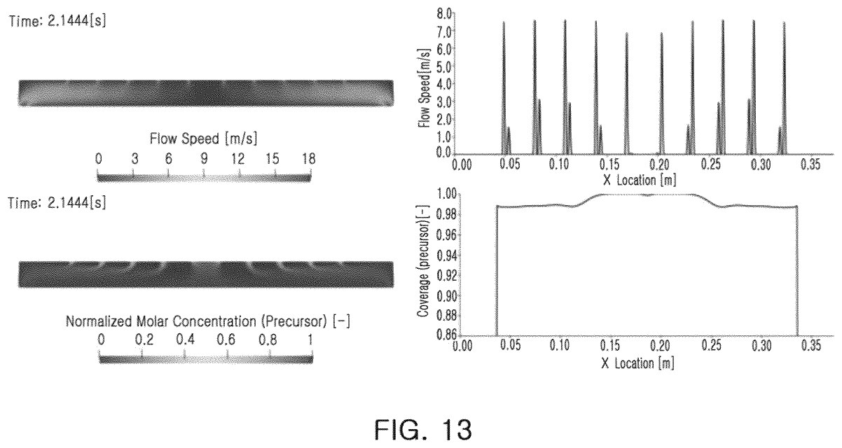

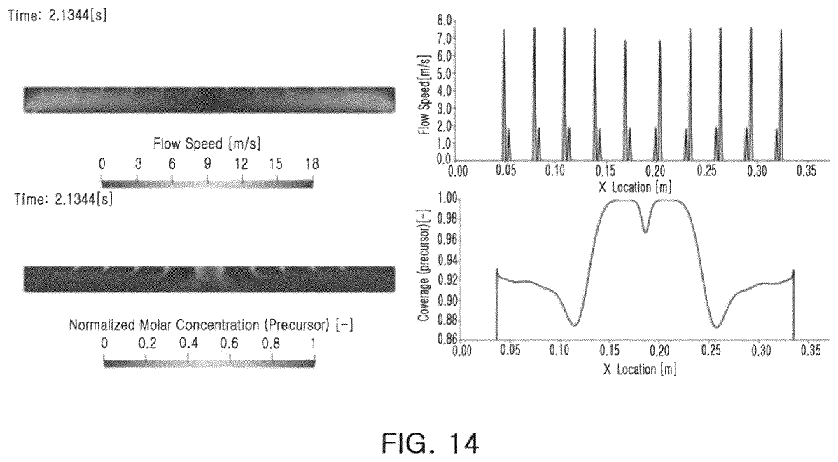

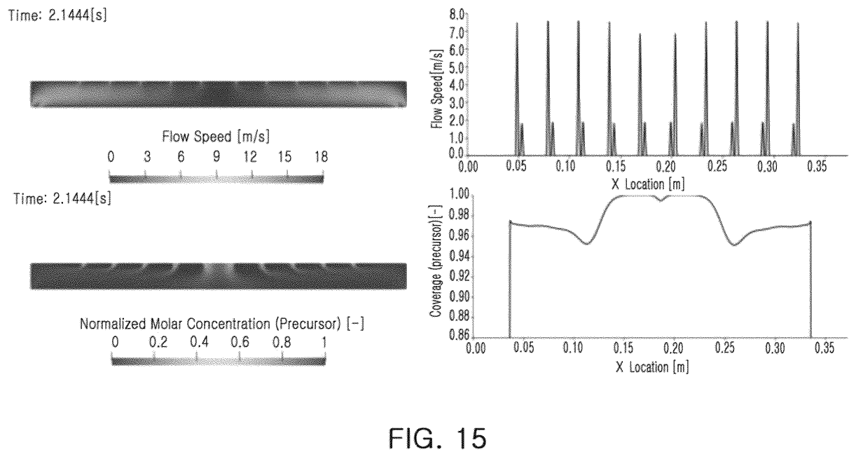

Referring to the performance results of the process, in the case of the atomic layer deposition apparatus 100 (see FIG. 1) according to an example embodiment, as illustrated in FIG. 12, the minimum value of the coverage becomes 0.95 or greater at 2.1344 s, and in the case of the atomic layer deposition apparatus 10 (see FIG. 2) according to the related art, as illustrated in FIG. 15, the minimum value of the coverage becomes 0.95 or more at 2.1444 s. At 2.1344 s, which is a point in which at which the atomic layer deposition apparatus 100 (see FIG. 1) according to an example embodiment satisfies a reference condition (i.e., a point in which at which the minimum value of the coverage becomes 0.95 or greater), the minimum value of the coverage of the atomic layer deposition apparatus 10 (see FIG. 2) according to the related art is only 0.87 as illustrated in FIG. 14, indicating that the distribution is still large. Also, as illustrated in FIG. 15, at 2.1444 s, which is a point in which at which the atomic layer deposition apparatus 10 (see FIG. 2) according to the related art satisfies the reference condition (i.e., a point in time at which the minimum value of the coverage becomes 0.95 or greater), the minimum value of the coverage through the atomic layer deposition apparatus 100 (see FIG. 1) according to an example embodiment becomes 0.99 as illustrated in FIG. 13, indicating that the maximum value is reached at all positions.

Also, comparing the results illustrated in FIGS. 12 to 15, the atomic layer deposition apparatus 100 (see FIG. 1) according to an example embodiment may complete the precursor spraying operation about 7.4% faster than the atomic layer deposition apparatus 10 (see FIG. 2) according to the related art, so the process time may be shortened by the corresponding value and the process cost may be reduced by reducing the usage amount of the precursor.

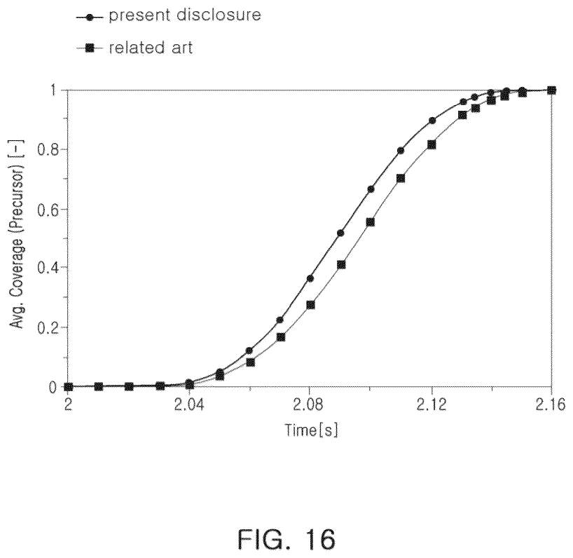

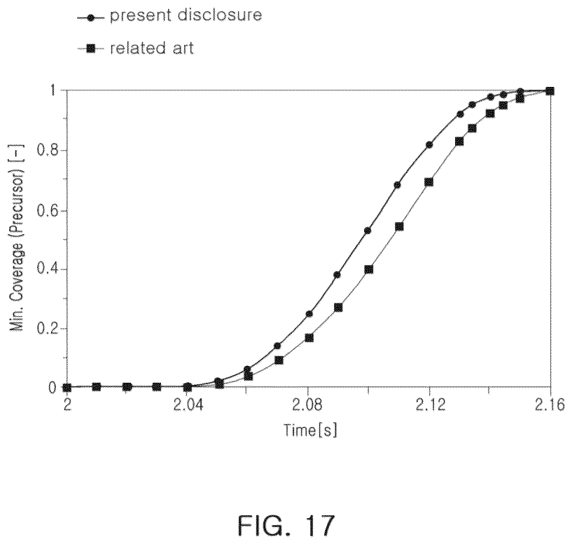

FIGS. 16 and 17 are graphs illustrating average and minimum values of the coverage of the atomic layer deposition apparatus 100 (see FIG. 1) according to an example embodiment and the atomic layer deposition apparatus 10 (see FIG. 2) according to the related art.

Referring to FIGS. 16 and 17, it can be seen that both the average and minimum values of the coverage of the atomic layer deposition apparatus 100 (see FIG. 1) according to an example embodiment are higher (i.e., better in terms of distribution) in all time zones than the atomic layer deposition apparatus 10 (see FIG. 2) according to the related art.

From this, it can be inferred that the effect similar to the operation of spraying the precursor described above may be achieved even in the operation of spraying the agent.

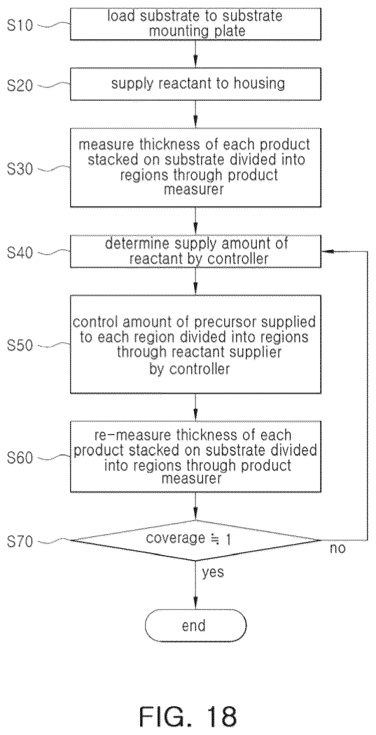

FIG. 18 is a flowchart illustrating an atomic layer deposition method according to an example embodiment.

Referring to FIGS. 1 and 18, first, the substrate 102 is loaded to and mounted on the substrate mounting plate 110 (S10). Thereafter, a reactant is supplied to the housing 120 through the reactant supplier 130 (S20). Here, a case in which a precursor is supplied as the reactant is described as an example. Also, at an initial stage of a deposition process of the precursor, only a transport gas is sprayed without precursor spraying to stabilize a field, and then, the precursor is supplied.

Thereafter, the thicknesses of the product stacked on the upper surface of the substrate 102 in each of the five zones (zone 1 to zone 5) corresponding to a plurality of regions, for example, the first to fifth regions 133a to 133e are measured through the product measurer (S30).

Thereafter, the controller 150 determines the supply amount of the reactant supplied to the first to fifth regions 133a to 133e according to the thickness of the product stacked on the upper surface of the substrate 102 in the five zones (zone 1 to zone 5) detected by the product measurer 140 (S40). Briefly, the thickness of the precursor adsorbed to the surface of the substrate 102 by an adsorption reaction in each region is detected by the product measurer 140, and the controller 150 derives the amount of the precursor adsorbed to the surface of the substrate 102 through information on the thickness of the precursor adsorbed to the surface of the substrate 102. Thereafter, the controller 150 calculates a coverage per position and time by dividing the amount of the precursor adsorbed to the surface of the substrate 102 by the amount of precursor that may be maximally deposited per unit area of the substrate surface. Here, a surface having a coverage of 0 calculated by the controller 150 is a surface on which the precursor is not deposited, and a surface having a coverage of 1 is a surface on which the precursor is completely deposited. Also, the controller 150 calculates a product shortage through the coverage. Here, the product shortage is calculated by surface-integrating (1-coverage) in each region. Thereafter, the controller 150 determines the amount of the precursor supplied from the reactant supplier 130 on the substrate divided into a plurality of regions based on the product shortage.

Thereafter, the controller 150 controls the amount of precursor supplied to each of the regions divided into a plurality of regions through the reactant supplier 130 so that it is supplied (S50).

Thereafter, the thickness of each product stacked on the substrate divided into a plurality of regions is re-measured through the product measurer (S60).

Thereafter, the controller 150 determines whether the coverage is approximately close to 1 through information on the thickness of the product in the regions corresponding to the first to fifth regions 133a to 133e detected by the product measurer 140 (S70).

Here, if the coverage is not close to 1, the controller 150 determines the supply amount of the reactant supplied to the first to fifth regions 133a to 133e according to the thickness of the product in the regions corresponding to the first to fifth regions 133a to 133e detected by the product measurer 140 (S40). Thereafter, the controller 150 controls the amount of the precursor supplied to each of the regions divided into a plurality of regions through the reactant supplier 130 so that it is supplied (S50).

Thereafter, the thickness of each product stacked on the substrate divided into a plurality of regions is re-measured through the product measurer (S60).

When the coverage is close to 1, the controller 150 stops supplying the reactant and terminates the precursor spraying operation. Here, when the coverage is close to 1, the coverage may have a value of 0.99 or greater.

The aforementioned atomic layer deposition method may be applied in the same manner as the aforementioned precursor injection operation in the operation of spraying the agent.

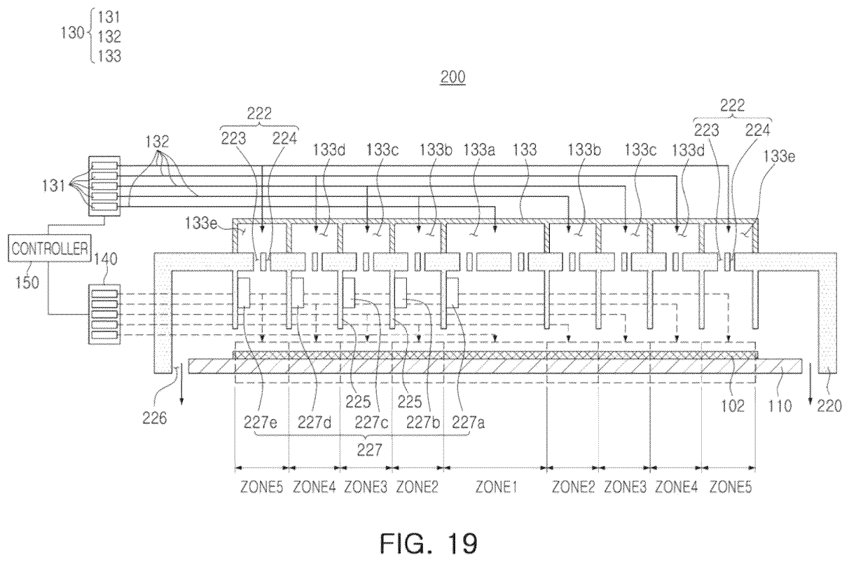

FIG. 19 is a configuration diagram illustrating an atomic layer deposition apparatus according to an example embodiment.

Referring to FIG. 19, an atomic layer deposition apparatus 200 according to an example embodiment includes a substrate mounting plate 110, a housing 220, a reactant supplier 130, a product measurer 140, and a controller 150.

The substrate mounting plate 110, the reactant supplier 130, the product measurer 140, and the controller 150 are substantially the same as the components described above, so a detailed description thereof is omitted here.

The housing 220 may have an internal space in which the substrate mounting plate 110 is accommodated. As an example, the housing 220 may have a box shape with an open bottom. The housing 220 may include a plurality of supply holes 222 through which a reactant is supplied to the internal space of the housing 220. The supply hole 222 may include a precursor spray hole 223 into which a precursor supplied through a reactant supplier 130 is sprayed and an agent spray hole 224 disposed to be adjacent to the precursor spray hole 223 and into which an agent is sprayed through the reactant supplier 130. A pair of the precursor spray hole 223 and the agent spray hole 224 form a supply hole 222. As an example, the precursor spray hole 223 and the agent spray hole 224 may be selectively opened and closed. For example, when a precursor is supplied from a reactant supplier 130, the precursor spray hole 223 may be opened and the agent spray hole 224 may be closed, and when an agent is supplied from the reactant supplier 130, the precursor spray hole 223 may be closed and the agent spray hole 224 may be opened. To this end, the housing 220 may include an opening/closing member.

The housing 220 may include a partition wall 225 partitioning a lower region of the supply hole 222 into a plurality of regions. The partition wall 225 may be formed on the housing 220 and extend toward the substrate 102. In this manner, since the housing 220 is further provided with the partition wall 225, the reactant supplied by the reactant supplier 130 may be guided more stably to the regions divided into a plurality of partitions of the substrate 102. Accordingly, regardless of a supply speed of the reactant, the reactant may be supplied more stably to each region divided by a plurality of partitions. Accordingly, the reactant introduced into the housing 220 may be reduced from being mixed in the internal space of the housing 220 and supplied onto the substrate 102.

A flow rate detection sensor 227 capable of detecting a flow rate of the supplied reactant may be installed in the partition wall 225. The flow rate detection sensor 227 may include first to fifth flow rate detection sensors 227a to 227e corresponding to each region. The flow rate detection sensor 227 may be connected to the controller 150, and the controller 150 may more precisely control the supply amount of the reactant supplied from the reactant supplier 130 through information on the flow rate detected by the flow rate detection sensor 227, that is, information on the flow rate of the reactant supplied to the five zones (zone 1 to zone 5) detected by the first to fifth flow rate detection sensors 227a to 227e.

The lower portion of the housing 220 is open, and an outlet 226 may be formed between the housing 220 and the substrate mounting plate 110. Accordingly, since the substrate mounting plate 110 is disposed in the internal space of the housing 220, the precursor passing through the precursor spray hole 223 and flowing into the internal space of the housing 220 through the space formed between the substrate mounting plate 110 and the housing 220 and the agent passing through the agent spray hole 224 and flowing into the internal space of the housing 220 may be discharged to the outside of the housing 220 through the outlet 226.

As described above, the agent flowing into the housing 220 by the partition wall 225 may be reduced from being mixed in the internal space of the housing 220 and supplied onto the substrate 102.

In addition, the supply amount of the reactant supplied from the reactant supplier 130 may be controlled more precisely through information on the flow rate of the reactant supplied to the five zones (zone 1 to zone 5) detected by the first to fifth flow rate detection sensors 227a to 227e.

The atomic layer deposition apparatus capable of reducing a thickness distribution of the film deposited by an atomic layer deposition process and reducing process costs may be provided.

At least one of the components, elements, modules, units, or the like (collectively “components” in this paragraph) represented by a block or an equivalent indication (collectively “block”) in the above embodiments including the drawings such as FIGS. 1, 3, and 19, for example, controller, supplier, measurer, or the like, may carry out the above-described function or functions. These blocks may be physically implemented by analog and/or digital circuits such as logic gates, integrated circuits, microprocessors, microcontrollers, memory circuits, passive electronic components, active electronic components, optical components, hardwired circuits and the like, and may optionally be driven by a firmware. The circuits may, for example, be embodied in one or more semiconductor chips, or on substrate supports such as printed circuit boards and the like. The circuits constituting a block may be implemented by dedicated hardware, or by a processor (e.g., one or more programmed microprocessors and associated circuitry), or by a combination of dedicated hardware to perform some functions of the block and a processor to perform other functions of the block. Each block of the embodiments may be physically separated into two or more interacting and discrete blocks without departing from the scope of the disclosure. Likewise, the blocks of the embodiments may be physically combined into more complex blocks without departing from the scope of the disclosure.

While example embodiments have been illustrated and described above, it will be apparent to those skilled in the art that modifications and variations could be made without departing from the scope of the present disclosure as defined by the appended claims.

What is claimed is:

1. An atomic layer deposition apparatus comprising:
a substrate mounting plate configured to have a substrate mounted thereon;
a housing comprising an internal space in which the substrate mounting plate is accommodated;
a reactant supplier comprising a plurality of regions respectively corresponding to a plurality of zones of the substrate; and
a product measurer configured to measure a thickness of a product deposited on each of the plurality of zones,
wherein the housing further comprises a plurality of supply holes respectively corresponding to the plurality of regions and configured to allow a reactant to pass into the internal space from the reactant supplier, and
wherein the reactant supplier is configured to supply the reactant to the plurality of zones through the plurality of regions and the plurality of supply holes.

2. The atomic layer deposition apparatus of claim 1, wherein the reactant supplier comprises a reactant source and a plurality of reactant supply lines connected to the reactant source and connected to the plurality of regions.

3. The atomic layer deposition apparatus of claim 2, further comprising a controller connected to the reactant supplier and the product measurer.

4. The atomic layer deposition apparatus of claim 3, wherein the controller is configured to control an amount of the reactant supplied by the reactant supplier to at least one of the plurality of zones based on the measured thickness of the product deposited on at least one of the plurality of zones.

5. The atomic layer deposition apparatus of claim 4, wherein the controller is further configured to control the reactant supplier to change at least one of the amount of the reactant supplied to at least one of the plurality of regions and an amount of time the reactant is supplied to at least one of the plurality of regions.

6. The atomic layer deposition apparatus of claim 1, wherein each of the plurality of supply holes comprises a precursor spray hole and an agent spray hole adjacent to the precursor spray hole.

7. The atomic layer deposition apparatus of claim 2, wherein the reactant supplier further comprises a cover member covering the plurality of supply holes, wherein the cover member is divided into the plurality of regions, and
wherein the plurality of reactant supply lines are respectively connected to the plurality of regions of the cover member.

8. The atomic layer deposition apparatus of claim 1, wherein the housing comprises at least one partition wall dividing the plurality of supply holes into the plurality of regions.

9. The atomic layer deposition apparatus of claim 1, wherein the product measurer comprises a plurality of optical sensors configured to respectively measure the thickness of the product deposited on the plurality of zones.

10. The atomic layer deposition apparatus of claim 3, wherein the controller is configured to control the reactant supplier to adjust an amount of the reactant that is supplied based on a comparison of a preset reference amount with the measured thickness of the product deposited on each of the plurality of zones.

11. An atomic layer deposition apparatus comprising:
a substrate mounting plate configured to have a substrate mounted thereon;
a housing comprising an internal space in which the substrate mounting plate is accommodated;
a reactant supplier comprising a plurality of regions which respectively correspond to a plurality of zones of the substrate; and
a product measurer configured to measure a thickness of a product deposited on each of the plurality of zones,
wherein the housing further comprises a plurality of supply holes respectively corresponding to the plurality of regions and configured to allow a reactant to pass into the internal space from the reactant supplier,
wherein the reactant supplier further comprises a reactant source, a plurality of reactant supply lines connected to the reactant source and respectively connected to the plurality of regions, and a cover member covering the plurality of supply holes,
wherein the cover member is divided into the plurality of regions, and
wherein the plurality of reactant supply lines are respectively connected to the plurality of regions of the cover member.

12. The atomic layer deposition apparatus of claim 11, further comprising a controller connected to the reactant supplier and the product measurer.

13. The atomic layer deposition apparatus of claim 12, wherein the controller is configured to control the reactant supplier to adjust an amount of the reactant supplied to at least one of the plurality of zones based on the measured thickness of the product deposited on at least one of the plurality of zones.

14. The atomic layer deposition apparatus of claim 13, wherein the controller is further configured to control the reactant supplier to change at least one of the amount of the reactant supplied to at least one of the plurality of regions and an amount of time the reactant is supplied to at least one of the plurality of regions.

15. The atomic layer deposition apparatus of claim 11, wherein each of the plurality of supply holes comprises a precursor spray hole and an agent spray hole adjacent to the precursor spray hole.

16. The atomic layer deposition apparatus of claim 11, wherein the product measurer comprises a plurality of optical sensors configured to respectively measure the thickness of the product deposited on the respective zones among the plurality of zones.

17. The atomic layer deposition apparatus of claim 12, wherein the controller is configured to control the reactant supplier to adjust an amount of the reactant that is supplied based on a comparison of a present reference amount with the measured thickness of the product deposited on each of the plurality of zones.

18. An atomic layer deposition apparatus comprising:
a substrate mounting plate configured to have a substrate mounted thereon;
a housing comprising an internal space in which the substrate mounting plate is accommodated;
a reactant supplier configured to supply a reactant to be deposited on the substrate; and
a product measurer configured to measure a thickness of a product deposited on the substrate,
wherein the housing further comprises a plurality of supply holes configured to allow the reactant to pass into the internal space, and
wherein the product measurer comprises a plurality of optical sensors configured to respectively measure the thickness of the product deposited on each of a plurality of zones of the substrate.

19. The atomic layer deposition apparatus of claim 18, wherein the reactant supplier comprises a reactant source and a plurality of reactant supply lines connected to the reactant source and respectively connected to a plurality of divided regions of the reactant supplier.

20. The atomic layer deposition apparatus of claim 19, further comprising a controller connected to the reactant supplier and the product measurer.
